(19) United States
(12) Patent Application Publication
(10) Pub. No.: US 2013/0258611 A1
(43) Pub. Date: Oct. 3, 2013

(54) ELECTRONIC APPARATUS AND FIXING DEVICE THEREOF

(71) Applicants: Jen-Kung LI, New Taipei City (TW); Wen-Lin WU, New Taipei City (TW)

(72) Inventors: Jen-Kung LI, New Taipei City (TW); Wen-Lin WU, New Taipei City (TW)

(21) Appl. No.: 13/611,504

(22) Filed: Sep. 12, 2012

(30) Foreign Application Priority Data
Mar. 30, 2012 (TW) 101111491

(51) Int. Cl. H05K 7/00; F16B 2/14

(52) U.S. Cl. 361/748; 403/374.3

(57) ABSTRACT

The fixing device includes a main body, at least two sliding location elements and at least one location element. The main body includes a bolting structure for bolting with a component element. The sliding location elements are disposed on one side of the main body opposite the bolting structure. Each sliding location element includes a connecting portion connected to the main body and an extending portion connected to the connecting portion. The extending portion is substantially parallel to the main body. A spacing is kept between the main body and the extending portion for clamping and fixing a printed circuit board. The at least one location element is extended from the main body and is substantially parallel to the extending portion. The at least one location element is disposed between the sliding location elements and the bolting structure for fixing the printed circuit board.

### FIELD OF THE DISCLOSURE

The present disclosure relates to a fixing device and, more particularly, to a fixing device that is easy to be installed and is applied to assembling a printed circuit board and component elements thereof.

### BACKGROUND

Emboss positions of display panels are usually different for different electronic apparatuses. To successfully assembly electronic apparatuses, new printed circuit boards and new assembly structure components need to be designed for different display panels. For example, position of each electronic component on a printed circuit board needs to be bypassed while supporting effect between a printed circuit board and an assembly structure component also needs to be considered. However, this will increase assembly cost and complexity of the assembly process.

Some manufacturers design a supporting column component supporting between a printed circuit board and an assembly structure component to meet assembly requirements. The supporting column component has a certain height, so that its one end can be fixed to the printed circuit board, and the other end forms a plane to support the assembly structure component. However, the supporting column component only provides a supporting function of withstanding external pressures, but it cannot fix by screws and withstand external pulling force, and the assembly of the fixing device is therefore lack of stability. If a supporting column component capable of fixing screws is adopted, it is usually disposed at the edge or the corner of the printed circuit board to utilize a corresponding stop block to prevent the supporting column component from rotation with the screws when fixing them. As a result, the supporting column component can only be disposed on limited locations and cannot be used flexibly.

Therefore, it is desirable to provide a fixing device with effective fixing and supporting function between printed circuit boards and corresponding elements within electronic apparatuses to mitigate and/or obviate the aforementioned problems.

### SUMMARY OF THE DISCLOSURE

It is an objective of the present disclosure to provide an fixing device that is easy to dispose and is applied to assembling a printed circuit board and corresponding component elements.

To achieve the above objective, a fixing device of the present disclosure includes a main body, at least two sliding location elements and at least one location element. The main body includes a bolting structure for bolting with an electronic element. The at least two sliding location elements are disposed on one side of the main body with the bolting structure. Each sliding location element includes a connecting portion and an extending portion. The connecting portion is connected to the main body, and the extending portion is connected to the connecting portion and is substantially parallel to the main body. A spacing is kept between the main body and the extending portion for clamping and fixing a printed circuit board. The at least one location element is extended from the main body and is substantially parallel to the extending portion. The at least one location element is disposed between the at least two sliding location elements and the bolting structure for fixing the printed circuit board.

In one embodiment of the present disclosure, the main body further includes a set of elastic arm structures disposed between the at least two sliding location elements and the bolting structure.

In one embodiment of the present disclosure, the main body further includes a conductive and elastic element for providing a grounding function.

The present disclosure further includes an electronic apparatus utilizing the fixing device as described above. The electronic apparatus comprises a printed circuit board, an electronic element and at least one fixing device as mentioned above. The at least one fixing device is fixed to the printed circuit board, and provides a function of fixing the electronic element to assemble it to the printed circuit board.

In one embodiment of the present disclosure, the printed circuit board includes at least one set of slots, and each set of slots includes at least two sliding slots corresponding to the at least two sliding location elements and at least one location slot corresponding to the at least one location element, wherein each sliding slot is substantially perpendicular to the at least one location slot.

The fixing device of the present disclosure can be easily assembled to and disassembled from a printed circuit board, provides a more stable element fixing and supporting effect, and can be flexibly disposed on any position of the printed circuit board.

### BRIEF DESCRIPTION OF THE DRAWINGS

FIG. 1A is a schematic structural diagram of a fixing device in accordance with a first embodiment of the present disclosure.

FIG. 1B is a schematic structural diagram of the fixing device of another view point in accordance with the first embodiment of the present disclosure.

FIG. 2A is a schematic diagram of the fixing device in accordance with the first embodiment of the present disclosure before assembled to a printed circuit board.

FIG. 2B is a schematic diagram of the fixing device in accordance with the first embodiment of the present disclosure after assembled to the printed circuit board.

FIG. 3 is a cross-session of the fixing device in accordance with the first embodiment of the present disclosure when bolting an electronic element with the printed circuit board.

FIG. 4 is a schematic diagram of a fixing device in accordance with a second embodiment of the present disclosure after assembled to the printed circuit board.

FIG. 5A is a schematic structural diagram of a fixing device in accordance with a third embodiment of the present disclosure.

FIG. 5B is a schematic structural diagram of the fixing device of another view point in accordance with the third embodiment of the present disclosure.

FIG. 6A is a schematic diagram of the fixing device in accordance with the third embodiment of the present disclosure before assembled to the printed circuit board.

FIG. 6B is a schematic diagram of the fixing device in accordance with the third embodiment of the present disclosure after assembled to the printed circuit board.

### DETAILED DESCRIPTION

The advantages and innovative features of the disclosure will become more apparent from the following detailed description when taken in conjunction with the accompanying drawings.

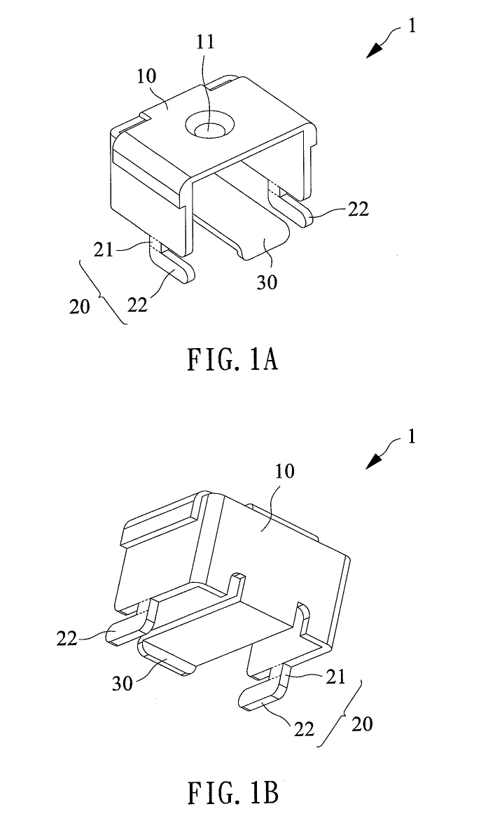

Please refer to FIG. 1A and FIG. 1B. FIG. 1A is a schematic structural diagram of a fixing device 1 in accordance with a first embodiment of the present disclosure. FIG. 1B is a schematic structural diagram of the fixing device 1 of another view point in accordance with the first embodiment of the present disclosure.

In one embodiment of the present disclosure, electronic apparatuses include televisions, displayers, computers and other 3C electronic products. The fixing device 1 of the present disclosure is used for, but not limited to, assembling of a printed circuit board or elements within an electronic apparatus and a outer housing of the electronic apparatus.

As shown in FIG. 1A and FIG. 1B, the fixing device 1 of the present application comprises a main body 10, at least two sliding location elements 20 and at least one location element 30. The fixing device 1 can be made of elastic materials, such as metal or plastic materials. The material can be changed according to different designs, metal is preferred in this embodiment. The main body 10 includes a bolting structure 11 disposed on one side of the main body 10, for bolting with an electronic element (not shown in FIG. 1A and FIG. 1B). In this embodiment, the bolting structure 11 is a screw hole used accompanying with a bolt or other similar elements for bolting electronic elements, but this is not used to limit the scope of the present disclosure.

The at least two sliding location elements 20 are disposed on the other side of the main body 10 facing the bolting structure 11, i.e. the side of the main body 10 opposite the bolting structure 11. Each sliding location element 20 includes a connecting portion 21 and an extending portion 22. The connecting portion 21 is connected to the main body 10; the extending portion 22 is connected to the connecting portion 21, and a extending direction of the extending portion 22 is substantially paralleled to the main body 10, so that each sliding location element 20 as a whole forms an L-shaped structure. A spacing is kept between the main body 10 and the extending portion 22 for clamping and fixing a printed circuit board (not shown in FIG. 1A and FIG. 1B), and a width of the spacing is not less than a thickness of the printed circuit board.

In this embodiment, at least one location element 30 extends from the main body 10 along the extending direction of the extending portions 22, and is substantially parallel to the extending portions 22 to form a hook structure. The at least one location element 30 is disposed between the at least two sliding location elements 20 and the bolting structure 11, so that the fixing device 1 of the present disclosure provides a fixation effect via the at least one location element 30 when assembled to the printed circuit board.

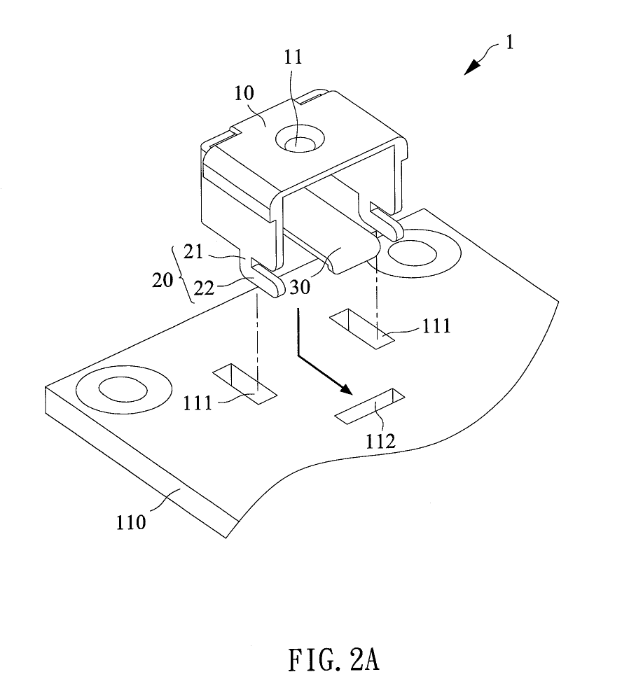

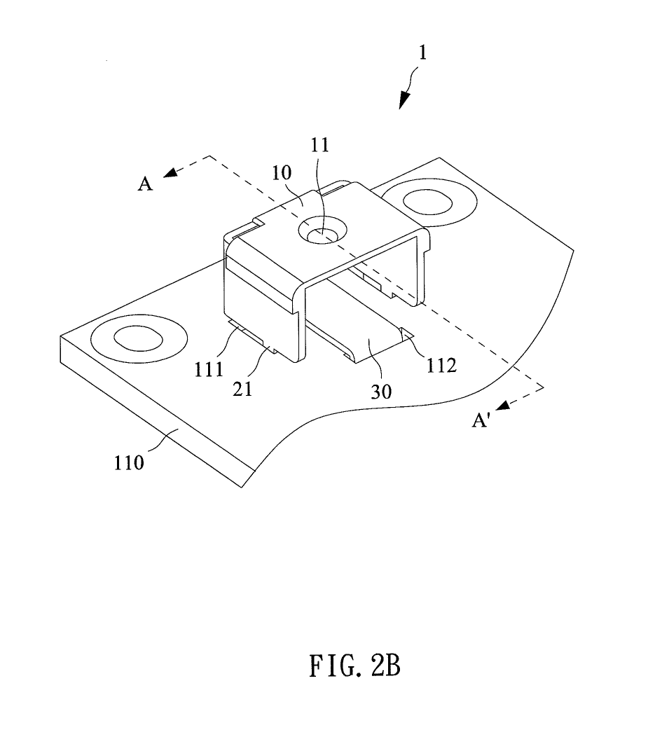

Please refer to FIG. 2A and FIG. 2B. FIG. 2A is a schematic diagram of the fixing device 1 in accordance with the first embodiment of the present disclosure before assembled to a printed circuit board 110. FIG. 2B is a schematic diagram of the fixing device 1 in accordance with the first embodiment of the present disclosure after being assembled to the printed circuit board 110.

As shown in FIG. 2A, the fixing device 1 of the present disclosure is firmly disposed on the printed circuit board 110 by the sliding location elements 20 and the location element 30. A set of slots can be designed on the printed circuit board 110 to achieve a fixation effect between the printed circuit board 110 and the fixing device 1 of the present disclosure. The set of slots includes at least two sliding slots 111 corresponding to the at least two sliding location elements 20 and at least one location slot 112 corresponding to the at least one location element 30. A length of each sliding slot 111 is not less than a length of the extending portion 22, so that the extending portion 22 of the sliding location element 20 can pass through the sliding slot 111 when the fixing device 1 is assembled to the printed circuit board 110.

In the assembling process of the fixing device 1, the extending portion 22 of each sliding location elements 20 is passed through each corresponding sliding slot 111 first. The connecting portion 21 of each sliding location elements 20 now can move along each sliding slots 111 because the distance between the main body 10 and the extending portions 22 is not less than the thickness of the printed circuit board 110. Then, pushing the fixing device 1 following the direction of the arrow in FIG. 2A until the at least one location element 30 gets into the at least one location slot 112. Meanwhile, the extending portions 22 of the sliding location elements 20 combined with bottom of the main body 10 clamp the printed circuit board 110 to achieve the fixation effect, as shown in FIG. 2B.

Accordingly, the fixing device 1 of the present disclosure provides a three-point fixation effect through the sliding location elements 20 and the location element 30. The assembling of the at least two sliding location elements 20 and the printed circuit board 110 prevents the fixing device 1 from rotation and provides better supporting when bolting the bolting structure 11 of the main body 10 by a bolt or a screw. The assembling of the at least one location element 30 and the printed circuit board 110 provides a stable location effect of the fixing device 1 of the present disclosure.

When a user wants to disassemble the fixing device 1 of the present disclosure from the printed circuit board 110, the at least one location element 30 is separated from the at least one location slot 112 first; second, the fixing device 1 of the present disclosure is pushed along the opposite direction of the arrow in FIG. 2A until the extending portions 22 of the sliding location elements 20 can pass through the sliding slots 111; and then, the fixing device 1 of the present disclosure can be disassembled from the printed circuit board 110. The fixing device 1 of the present disclosure can be reused for assembling.

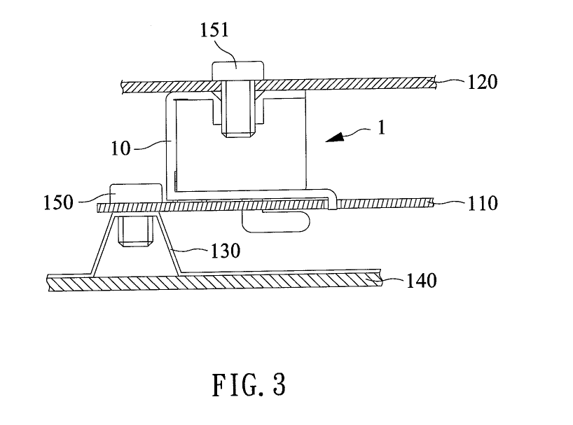

Please refer to FIG. 3, which is a cross-session of the fixing device 1 in accordance with the first embodiment of the present disclosure when bolting a component element 120 with the printed circuit board 110.

FIG. 3 is a cross-session derived from slitting along the dashed line segment A-A′ in FIG. 2B after bolting the electronic element 120 with the printed circuit board 110 using the fixing device 1 of the present disclosure. As shown in FIG. 3, taking a flat panel television as an example of the electronic apparatus 100, the printed circuit board 110 can be fixed inside a frame 130 of the electronic apparatus 100 by a bolt 150 or other bolting elements, and a display panel 140 is assembled onto the frame 130. The fixing device 1 fixed on the printed circuit board 110 can also be bolted with a component element 120 (such as the rear cover of the device) of the electronic apparatus 100 by a bolt 151 or other bolting elements. Therefore, the fixing device 1 of the present disclosure not only provides a fixation effect between the printed circuit board 110 and the electronic element 120, but also acts as a supporting element between them to ensure the whole structure more stable and for assembling or disassembling easy.

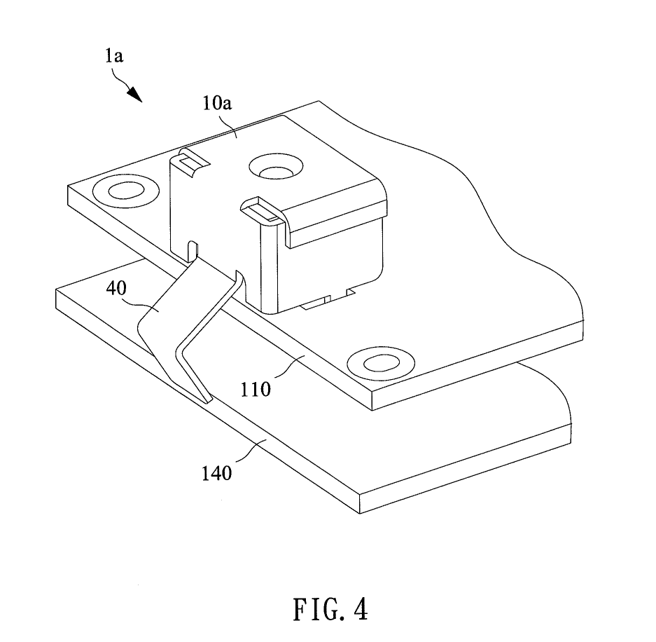

Please refer to FIG. 4, which is a schematic diagram of a fixing device 1a in accordance with a second embodiment of the present disclosure after assembled to the printed circuit board 110.

This embodiment is a variation of the first embodiment. As shown in FIG. 4, the main body 10a of the fixing device 1a of the present disclosure further includes a conductive and elastic element 40, which extends from the main body 10a to provide a grounding function. In this embodiment, the conductive and elastic element 40 is a metal dome. But the realization of the conductive and elastic element 40 is not limited to this embodiment, for example, it can be replaced with a emboss structure or other fixing structures. When the fixing device 1a is disposed on the printed circuit board 110, the conductive and elastic element 40 has an elastic contact with the display panel 140 or the metal frame of the electronic apparatus to form a grounding connection, and thereby meets the requirement of electromagnetic shielding or electromagnetic interference prevention. But this is not used to limit the scope of the present disclosure.

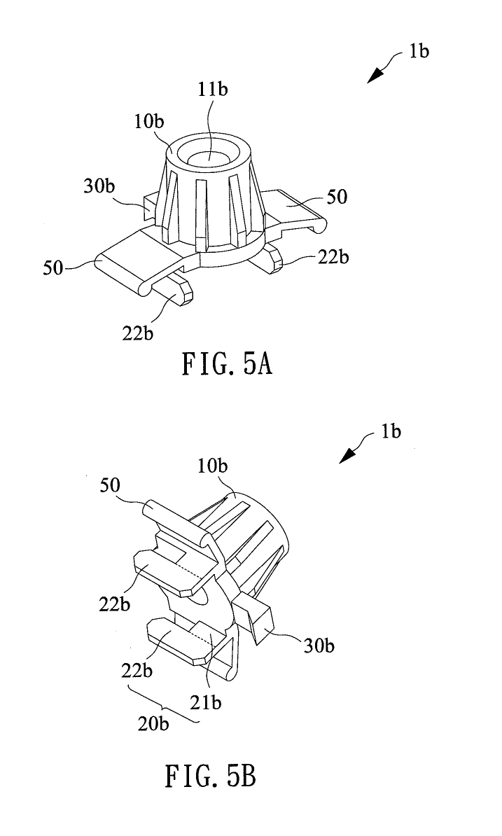

Please refer to FIG. 5A and FIG. 5B. FIG. 5A is a schematic structural diagram of a fixing device 1b in accordance with a third embodiment of the present disclosure. FIG. 5B is a schematic structural diagram of the fixing device 1b of another view point in accordance with the third embodiment of the present disclosure.

As shown in FIG. 5A and FIG. 5B, the fixing device 1b comprises a main body 10b, at least two sliding location elements 20b and at least one location element 30b. The fixing device 1b can be made of elastic materials, such as metal or plastic materials. The material can be changed according to different designs, and plastic materials are preferred in this embodiment. The above-mentioned elements are similar to those of the first embodiment in technical features, and only the appearance structures are changed. To fit different assembling designs, in this embodiment, the at least one location element 30b extends from the main body 10b against the extending direction of the extending portions 22b, and is substantially paralleled to the extending portions 22b to form a hook structure and provide a fixation effect.

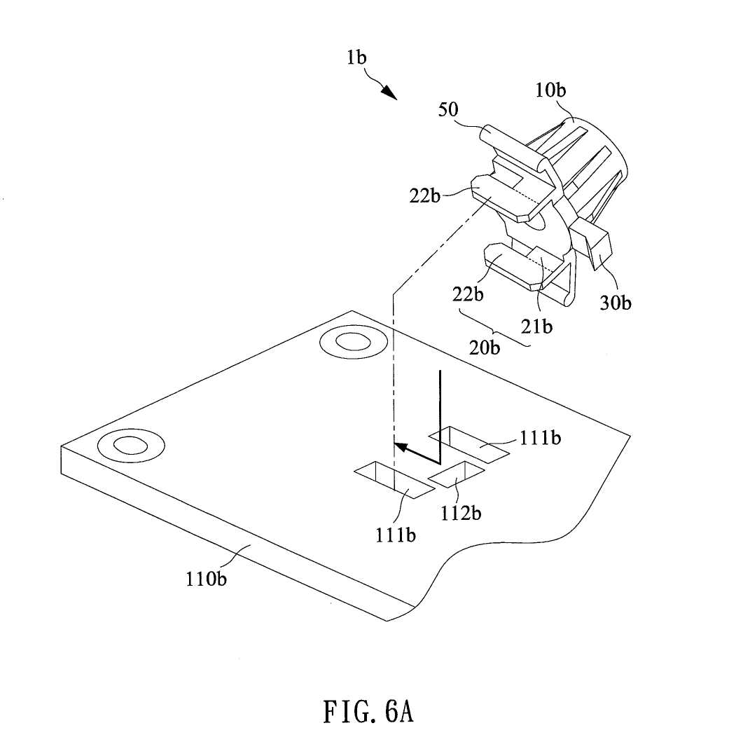

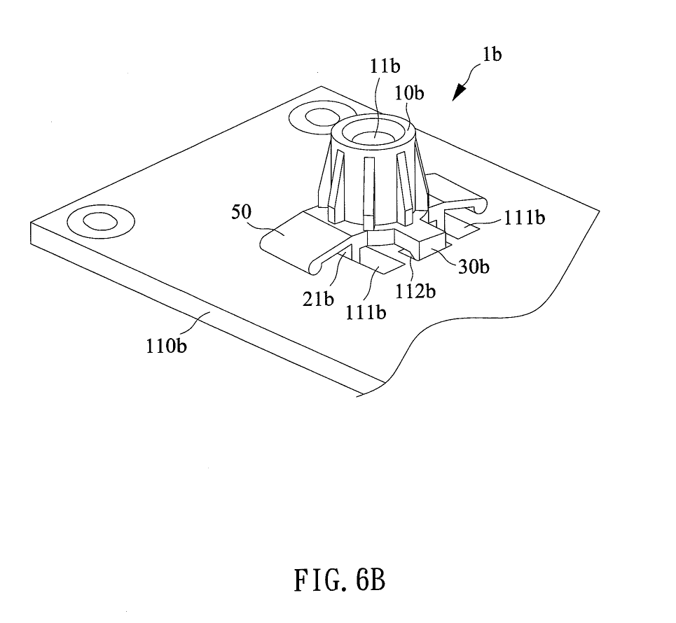

Please refer to FIG. 6A and FIG. 6B. FIG. 6A is a schematic diagram of the fixing device 1b in accordance with the third embodiment of the present disclosure before assembled to a printed circuit board 110b. FIG. 6B is a schematic diagram of the fixing device 1b in accordance with the third embodiment of the present disclosure after assembled to the printed circuit board 110b.

As shown in FIG. 6A, the fixing device 1b of the present disclosure is firmly disposed on the printed circuit board 110b through the sliding location elements 20b combined with the location element 30b. A set of slots can be designed on the printed circuit board 110b, positions of at least two sliding slots 111b and at least one location slot 112b of the set of slots are changed corresponding to the at least two sliding location elements 20b and the at least one location element 30b. According to this embodiment, the distance between the at least two sliding slots 111b and the at least one location slot is less than that of the first embodiment. The length of the sliding slots 111b is not less than the length of the extending portions 22b, so that the extending portions 22b of the sliding location elements 20b can pass through the sliding slots 111b when the fixing device 1b is assembled to the printed circuit board 110b.

In the assembling process of the fixing device 1b, the extending portion 22b of each sliding location element 20b is passed through each corresponding sliding slot 111b first. The connecting portion 21b of each sliding location elements 20b now can move along each sliding slot 111b because the distance between the main body 10b and the extending portions 22b is not less than the thickness of the printed circuit board 110b. Then, pushing the fixing device 1b following the direction of the arrow in FIG. 6A (i.e. the opposite direction of the arrow in FIG. 2A) until the at least one location element 30b gets into the at least one location slot 112b. Meanwhile, the extending portions 22b of the sliding location elements 20b combined with bottom of the main body 10b clamp the printed circuit board 110b to achieve the fixation effect, as shown in FIG. 6B.

Accordingly, the fixing device 1b of the present disclosure can also provide the same function as the first embodiment mentioned above.

Moreover, in this embodiment, the main body 10b of the fixing device 1b further comprises a set of elastic manipulator structures 50 extended from the main body 10b and disposed between the at least two sliding location elements 20b and the bolting structure 11b. The elastic manipulator structures 50 include two symmetric elastic manipulators. One end of each elastic manipulator connects to the main body 10b, and the other end extends slanting underneath the bottom of the main body 10b. Thus, when assembling the fixing device 1b to the printed circuit board 110b, the elasticity deformation of the elastic manipulator structures 50 provides the main body 10b of the fixing device 1b with supporting strength upwards to make sure the fixing device 1b assembled to the printed circuit board 110b more firmly.

The present disclosure further includes an electronic apparatus utilizing the fixing device as described above. As shown in FIG. 3, the electronic apparatus 100 comprises the printed circuit board 110, the electronic element 120 and at least one fixing device 1 (or 1a, 1b) mentioned above. The at least one fixing device 1 is fixed to the printed circuit board 110, and provides a function of fixing the electronic element 120 to assemble it to the printed circuit board 110. The number and disposed position of the fixing device 1 can be changed according to different design requirements, and there are corresponding sets of slots as shown in FIG. 2A or FIG. 6A designed on the printed circuit board 110. Accordingly, the component element 120 can be combined with the printed circuit board 110 by the at least one fixing device 1, and the at least one fixing device 1 provides a fixation and supporting effect between the component element 120 and the printed circuit board 110.

It is noted that the above-mentioned embodiments are only for illustration. It is intended that the present disclosure cover modifications and variations of this disclosure provided they fall within the scope of the following claims and their equivalents. Therefore, it will be apparent to those skilled in the art that various modifications and variations can be made to the structure of the present disclosure without departing from the scope or spirit of the disclosure.

What is claimed is:

1. A fixing device, comprising:
a main body, comprising a bolting structure for bolting with a component element;
at least two sliding location elements, disposed on one side of the main body opposite the bolting structure, each sliding location element comprising a connecting portion and an extending portion, the connecting portion being connected to the main body, the extending portion being connected to the connecting portion and to being substantially parallel to the main body, and a spacing being kept between the main body and the extending portion for clamping and fixing a printed circuit board; and
at least one location element, extended from the main body and being substantially parallel to the extending portion, the at least one location element being disposed between the at least two sliding location elements and the bolting structure for fixing the printed circuit board.

2. The fixing device as claimed in claim 1, wherein the extending portions and the at least one location element extend substantially towards a same direction.

3. The fixing device as claimed in claim 1, wherein the extending portions and the at least one location element extend substantially along opposite directions.

4. The fixing device as claimed in claim 1, wherein the main body further comprises a set of elastic manipulator structures disposed between the at least two sliding location elements and the bolting structure.

5. The fixing device as claimed in claim 1, wherein the main body further comprises a conductive and elastic element for providing a grounding function.

6. The fixing device as claimed in claim 1, wherein a width of the spacing is not less than a thickness of the printed circuit board.

7. An electronic apparatus, comprising:
an component element;
a printed circuit board; and
at least one fixing device, fixed to the printed circuit board, each fixing device comprising:
a main body, comprising a bolting structure for bolting with the component element;
is at least two sliding location elements, disposed on one side of the main body opposite the bolting structure, each sliding location elements comprising a connecting portion and an extending portion, the connecting portion being connected to the main body, the extending portion extending from the connecting portion and being substantially parallel to the main body, and a spacing being kept between the main body and the extending portion for clamping and fixing the printed circuit board; and
at least one location element, extended from the main body and being substantially parallel to the extending portion, the at least one location element being disposed between the at least two sliding location elements and the bolting structure for fixing the printed circuit board.

8. The electronic apparatus as claimed in claim 7, wherein the extending portions and the at least one location element extend substantially towards a same direction.

9. The electronic apparatus as claimed in claim 7, wherein the extending portion and the at least one location element extend substantially along opposite directions.

10. The electronic apparatus as claimed in claim 7, wherein the main body further comprises a set of elastic arm structures disposed between the at least two sliding location elements and the bolting structure.

11. The electronic apparatus as claimed in claim 7, wherein the main body further comprises a conductive and elastic element for providing a grounding function.

12. The electronic apparatus as claimed in claim 7, wherein a width of the spacing is not less than a thickness of the printed circuit board.

13. The electronic apparatus as claimed in claim 7, wherein the printed circuit board comprises at least one set of slots, and each set of slots comprises at least two sliding slots corresponding to the at least two sliding location elements and at least one location slot corresponding to the at least one location element.

14. The electronic apparatus as claimed in claim 13, wherein a length of each sliding slot is not less than a length of the extending portion.
